(19) United States
(12) Patent Application Publication
(10) Pub. No.: US 2025/0107134 A1
(43) Pub. Date: Mar. 27, 2025

(54) kV-Class and Low RON Vertical ß-Ga2O3 HEMT-CAVET Power Switch

(71) Applicants: Houqiang FU, Chandler, AZ (US); Dawei WANG, Tempe, AZ (US); Dinusha HERATH MUDIYANSELAGE, Mesa, AZ (US)

(72) Inventors: Houqiang FU, Chandler, AZ (US); Dawei WANG, Tempe, AZ (US); Dinusha HERATH MUDIYANSELAGE, Mesa, AZ (US)

(21) Appl. No.: 18/892,930

(22) Filed: Sep. 23, 2024

Related U.S. Application Data
(60) Provisional application No. 63/584,756, filed on Sep. 22, 2023.

(51) Int. Cl. H01L 29/778; H01L 29/24

(52) U.S. Cl. CPC H10D 30/477; H10D 62/80

(57) ABSTRACT

A high electron mobility transistor current-aperture vertical electron transistor includes a drain electrode, a source electrode, gate electrode, an n⁻ doped drift layer comprising β-Ga₂O₃, a first n⁺⁺ Ga₂O₃ layer between the drain electrode and the n⁻ doped drift layer, a current blocking layer, a second n⁺⁺ Ga₂O₃ layer between the current blocking layer and the source electrode, and a delta-doped β-(AlₓGa₁₋ₓ)₂O₃/Ga₂O₃ heterostructure between the portion of the n doped drift layer and the gate electrode. A portion of the n⁻ doped drift layer defines an aperture in the current blocking layer.

### CROSS-REFERENCE TO RELATED APPLICATION

This application claims the benefit of U.S. Patent Application No. 63/584,756 filed on Sep. 22, 2023, which is incorporated.

### STATEMENT OF GOVERNMENT SUPPORT

This invention was made with government support under 2302696 awarded by the National Science Foundation and under DE-SC0021230 awarded by the Department of Energy. The government has certain rights in the invention.

### TECHNICAL FIELD

This invention relates to β-Ga₂O₃ high electron mobility transistor current-aperture vertical electron transistors (HEMT-CAVETs) fabricated by introducing delta-doped β-(AlₓGa₁₋ₓ)₂O₃/Ga₂O₃ (x=0.2) heterostructure into the CAVETs.

### BACKGROUND

Beta-phase gallium oxide (β-Ga₂O₃) has been used in high-power, high-voltage, and high-frequency applications due at least in part to its ultrawide bandgap (˜4.8 eV), high critical electric field (˜8 MV/cm), and large Baliga's figure of merit. Compared with lateral devices such as high electron mobility transistors (HEMTs), vertical devices have advantages in high power applications, including higher voltage and current handling capability, immunity to surface-related issues, simpler cooling requirement, smaller chip area, and scalability. β-Ga₂O₃ based vertical transistors such as current aperture vertical electron transistors (CAVETs) and vertical fin-MOSFETs have been demonstrated. However, their device performance is far from the β-Ga₂O₃ material limit. Deep etching is typically required in β-Ga₂O₃ fin-MOSFETs to overcome drain-induced barrier lowering (DIBL) and the resulting low breakdown voltage (BV).

### SUMMARY

This disclosure describes design and modeling of enhancement-mode β-Ga₂O₃ current-aperture vertical electron transistors (CAVETs) using TCAD simulation. A β-Ga₂O₃ CAVET (i.e., HEMT-CAVETs) was proposed by introducing delta-doped β-(AlₓGa₁₋ₓ)₂O₃/Ga₂O₃ (x=0.2) heterostructure into CAVETs. The HEMT-CAVETs showed improvements in electron modulation, ON-state resistance (R_{ON}), and leakage due to the confined two-dimensional electron gas (2DEG) channel. The design space of doping, channel length (L_{ch}), and aperture length (Lₐₚ) on the device threshold voltages (V_{TH}), R_{ON}, breakdown voltage (BV), and OFF-state leakage were systematically investigated. With increasing delta-doping concentration, the HEMT-CAVETs showed smaller R_{ON} compared with the conventional CAVETs. The OFF-state leakage from the aperture and the current blocking layers (CBLs) in the β-Ga₂O₃ CAVETs was studied. Larger L_{ch} prevented the OFF-state leakage current from the aperture and increased BV, but it also increased the R_{ON} due to larger channel resistance. Small Lₐₚ could dramatically increase device R_{ON} due to the encroachment of the aperture by the depletion regions from the CBLs. The CBL breakdown played a key role in the device BV. The BV of the CBL increased with increasing CBL thickness and acceptor doping concentration, where kV-level BV and high peak electric fields of ˜8 MV/cm can be obtained with optimized CBLs. These results relate to kV-class low R_{ON} β-Ga₂O₃ CAVETs for high power, high voltage, and high frequency applications.

In a general aspect, a high electron mobility transistor current-aperture vertical electron transistor includes a drain electrode, a source electrode, gate electrode, an n⁻ doped drift layer comprising β-Ga₂O₃, a first n⁺⁺ Ga₂O₃ layer between the drain electrode and the n doped drift layer, a current blocking layer, a second n⁺⁺ Ga₂O₃ layer between the current blocking layer and the source electrode, and a delta-doped β-(AlₓGa₁₋ₓ)₂O₃/Ga₂O₃ heterostructure between the portion of the n doped drift layer and the gate electrode. A portion of the n⁻ doped drift layer defines an aperture in the current blocking layer.

Implementations of the general aspect may include one or more of the following features.

The delta-doped β-(AlₓGa₁₋ₓ)₂O₃/Ga₂O₃ heterostructure includes a delta-doped β-(AlₓGa₁₋ₓ)₂O₃ layer and unintentionally doped β-Ga₂O₃ layer. The delta-doped β-(AlₓGa₁₋ₓ)₂O₃ layer has a thickness in a range of about 100 nm to about 500 nm. The delta-doped β-(AlₓGa₁₋ₓ)₂O₃ layer includes a delta-doped region having a thickness in a range of about 1 nm to about 10 nm (e.g., about 5 nm) and a doping concentration in a range of about 1×10¹⁸ cm⁻³ to about 1×10¹⁹ cm⁻³ (e.g., about 1×10¹⁸ cm⁻³). The doping concentration is inversely related to a threshold voltage of the transistor. The (AlₓGa₁₋ₓ)₂O₃ layer has a thickness in a range of about 25 nm to about 75 nm (e.g., about 50 nm). The unintentionally doped β-Ga₂O₃ layer defines a 2D electron gas channel between portions of the second n⁺⁺ Ga₂O₃. Dopants in the delta-doped β-(AlₓGa₁₋ₓ)₂O₃ layer are separated from the 2D electron gas channel.

A channel length, defined as the distance between an edge of the second n⁺⁺ Ga₂O₃ layer and an interface between the current blocking layer and the n⁻ doped drift layer at the aperture, is in a range of about 1 μm to about 11 μm. The length of the channel is selected to maximize breakdown voltage and minimize ON-state resistance of the transistor. The length of the of the channel is selected to prevent OFF-state leakage current from the aperture. A length of the aperture between portions of the current blocking layer is in a range of about 1 μm to about 20 μm.

A length of the current blocking layer is in a range of about 1 μm to about 3 μm. A breakdown voltage of the current blocking layer increases with increasing thickness of the current blocking layer. An acceptor doping concentration in the current blocking layer is in a range of about 1×10¹⁸ cm⁻³ to about 3×10¹⁸ cm⁻³. A breakdown voltage of the current blocking layer increases with an increase in the acceptor doping concentration in the current blocking layer. A power figure of merit of the transistor increases with an increasing thickness of the current blocking layer and acceptor doping in the current blocking layer. A peak electric field of the transistor increases with an increase in thickness of the current blocking layer in a range of about 0.8 μm to about 6 μm.

Advantages include low reverse leakage and high breakdown voltage of the device, incorporation of vertical current handling structure compared to known lateral current handling structures, and enhanced power conversion efficiency with low on resistance and high off-state breakdown voltage.

The details of one or more embodiments of the subject matter of this disclosure are set forth in the accompanying drawings and the description. Other features, aspects, and advantages of the subject matter will become apparent from the description, the drawings, and the claims.

### BRIEF DESCRIPTION OF DRAWINGS

FIG. 1A is a schematic diagram of a simulated conventional β-Ga₂O₃ CAVET. FIG. 1B shows an energy band diagram extracted from the cutline in FIG. 1A. FIG. 1C is a schematic diagram of the simulated β-Ga₂O₃ CAVET with delta-doped β-(AlₓGa₁₋ₓ)₂O₃/Ga₂O₃ (x=0.2) heterostructure (HEMT-CAVET). FIG. 1D shows an energy band diagram extracted from the cutline in FIG. 1C.

FIG. 2A shows transfer curves of the conventional β-Ga₂O₃ CAVETs. “Experiment” refers to data from M. H. Wong et al., “Enhancement-Mode β-Ga₂O₃ Current Aperture Vertical MOSFETs With N-Ion-Implanted Blocker,” IEEE Electron Device Letters, vol. 41, no. 2, pp. 296-299, 2020, and the calibration curve is the calibration result from this simulation. The other curves are the simulated results with different doping concentrations in channel layer of conventional CAVET. FIG. 2B shows simulated transfer curves of HEMT-CAVETs with different delta-doping concentrations. FIG. 2C shows simulated transfer curves of the β-Ga₂O₃ HEMT-CAVETs with different doping concentrations in channel layer. FIG. 2D is a comparison of R_{ON} and V_{TH} between the conventional CAVETs and HEMT-CAVETs.

FIG. 3A shows experimental and simulated breakdown I_{DS}-V_{DS} curves of conventional CAVETs and HEMT-CAVETs. FIG. 3B shows breakdown characteristics of conventional CAVETs with different doping concentrations in the channel layer. FIG. 3C shows current density distribution of conventional CAVETs at V_{DS}=200 V. FIG. 3D shows current density distribution of conventional CAVETs at V_{DS}=265 V (i.e., BV). FIG. 3E shows current density distribution of HEMT-CAVETs at V_{DS}=265 V.

FIG. 4A shows band structure of a conventional CAVET extracted from cutline 1 in FIG. 3D. FIG. 4B shows band structure of HEMT-CAVET extracted from cutline 2 in FIG. 3E. FIG. 4C shows band structure of HEMT-CAVET extracted from cutline 3 in FIG. 3E. FIG. 4D shows 2D electric field distribution of conventional CAVET at V_{DS}=265 V. FIG. 4E shows 2D electric field distribution of HEMT-CAVET at V_{DS}=265 V. FIG. 4F shows electric field distribution in a horizontal direction extracted from cutline 4 and cutline 5 in FIGS. 4D and 4E.

FIG. 5A shows transfer curves of HEMT-CAVETs with increasing L_{ch} from 1 μm to 11 μm. FIG. 5B shows breakdown characteristics I_{DS}-V_{DS} curves of HEMT-CAVETs with channel length from 1 μm to 11 μm (Lₐₚ=20 μm).

FIG. 6 shows simulated BV and R_{ON} of β-Ga₂O₃ HEMT-CAVETs with different L_{ch}.

FIG. 7A shows transfer curves of HEMT-CAVETs with increasing Lₐₚ from 1 μm to 20 μm. FIG. 7B shows a schematic of resistance distribution in β-Ga₂O₃ HEMT-CAVETs. The inset shows a schematic of Rₐₚ (L_{ch}=5 μm).

FIG. 8A shows simulated BV with different CBL thickness from 0.8 μm to 3.0 μm. The inset shows simulated two-terminal CBL breakdown-testing structure. FIG. 8B shows extracted electric field in the vertical direction along the cutlines in FIGS. 8C-8G. FIGS. 8C-8G show the simulated electric field distribution at BV of HEMT-CAVETs with CBL thickness from 0.8 μm to 6.0 μm.

FIG. 9A shows BV versus acceptor doping concentrations in CBLs. FIG. 9B shows electric field distribution with different acceptor doping concentrations. FIGS. 9C-9E show the 2D electric field distribution mapped at BV of the devices with acceptors doping concentrations of 1.7, 2.5, and 3.0×10¹⁸ cm⁻³, respectively.

FIG. 10A shows power figure of merit versus different CBL thickness. FIG. 10B shows power figure of merit versus different acceptor doping concentrations in CBL.

FIG. 11 shows simulated breakdown field of (AlₓGa₁₋ₓ)₂O₃ Schottky barrier diode with different barrier heights from D. H. Mudiyanselage et al., “Ultrawide bandgap vertical β-(AlxGa1-x)₂O₃ Schottky barrier diodes on free-standing β-Ga₂O₃ substrates,” Journal of Vacuum Science & Technology A, vol. 41, pp. 023201, 2023.

### DETAILED DESCRIPTION

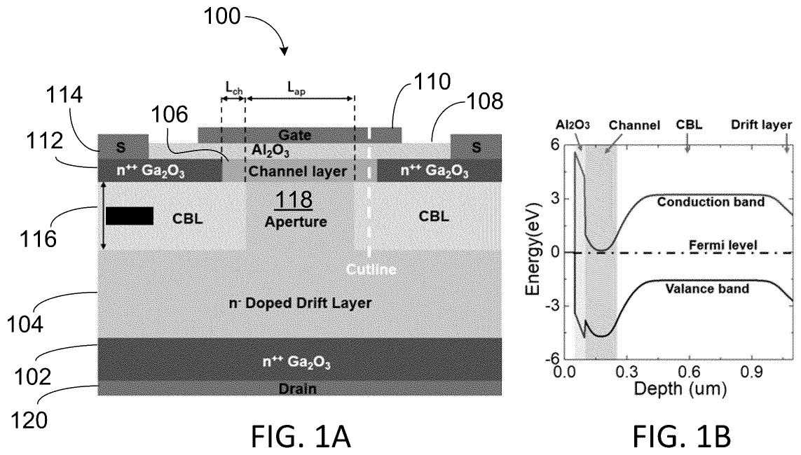

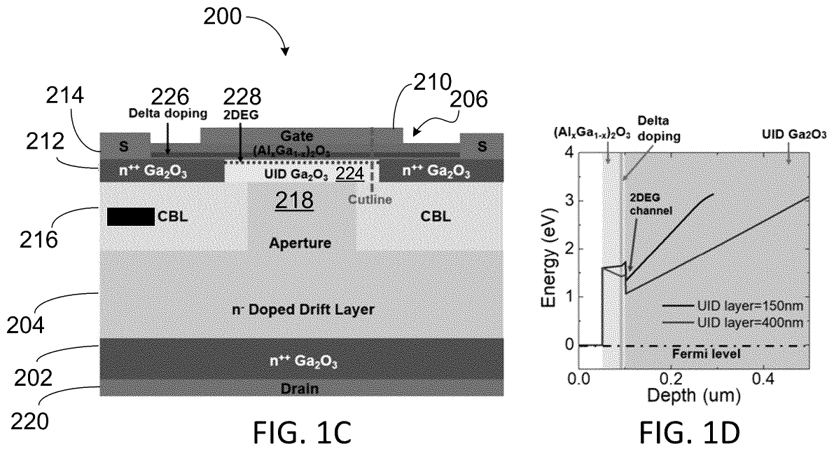

FIG. 1A is a schematic cross-sectional view of β-Ga₂O₃ current aperture vertical electron transistor (CAVET) 100. CAVET 100 includes n⁺⁺-doped β-Ga₂O₃ substrate 102, n-type drift layer 104, n⁺-doped channel layer 106, and Al₂O₃ dielectric layer 108 under gate 110. Two n⁺⁺-doped contact regions 112 are located under source contacts 114. Current blocking layer (CBL) regions 116 are located at both sides of aperture 118 above drift layer 104. Drain 120 is in contact with n⁺⁺-doped β-Ga₂O₃ substrate 102. The channel length (L_{ch}) is the distance between the edge of n⁺⁺-β-Ga₂O₃ contact region 112 and the edge of the CBL region 116 near a side of aperture 118. FIG. 1B shows an energy band diagram extracted from the cutline in FIG. 1A.

FIG. 1C is a schematic cross-sectional view of β-Ga₂O₃ high electron mobility transistor current-aperture vertical electron transistor (HEMT-CAVET) 200 fabricated by introducing delta-doped introducing delta-doped β-(AlₓGa₁₋ₓ)₂O₃/Ga₂O₃ (x=0.2) heterostructure into a CAVET. HEMT-CAVET 200 includes n⁺⁺-doped β-Ga₂O₃ substrate 202, n-type drift layer 204, delta-doped β-(AlₓGa₁₋ₓ)₂O₃/Ga₂O₃ heterostructure 206 under gate 210. Two n⁺⁺-doped contact regions 212 are located under source contacts 214. A portion of n⁻ doped drift layer 204 extends through CBL 216, defining aperture 218. Drain 220 is in contact with n⁺⁺-doped β-Ga₂O₃ substrate 202. Heterostructure 206 includes (AlₓGa₁₋ₓ)₂O₃/Ga₂O₃ layer 222 and UID β-Ga₂O₃ layer 224. For the delta-doping in β-(AlₓGa₁₋ₓ)₂O₃/Ga₂O₃ layer, a thin slab with uniform doping was used to represent the delta-doping region 226. Delta-doping region 226 is separated from the UID β-Ga₂O₃ layer and the β-(AlₓGa₁₋ₓ)₂O₃/Ga₂O₃ interface by a selected distance (e.g., similar to the thickness of the delta-doping region). UID β-Ga₂O₃ layer 224 defines 2D electron gas channel (2DEG) 228. FIG. 1D shows an energy band diagram extracted from the cutline in FIG. 1C.

The delta-doped β-(AlₓGa₁₋ₓ)₂O₃/Ga₂O₃ heterostructure includes a delta-doped β-(AlₓGa₁₋ₓ)₂O₃ layer and unintentionally doped β-Ga₂O₃ layer. The delta-doped β-(AlₓGa₁₋ₓ)₂O₃ layer has a thickness in a range of about 100 nm to about 500 nm. The delta-doped β-(AlₓGa₁₋ₓ)₂O₃ layer includes a delta-doped region having a thickness in a range of about 1 nm to about 10 nm (e.g., about 5 nm) and a doping concentration in a range of about 1×10¹⁸ cm⁻³ to about 1×10¹⁹ cm⁻³ (e.g., about 1×10¹⁸ cm⁻³). The doping concentration is inversely related to a threshold voltage of the transistor. The (AlₓGa₁₋ₓ)₂O₃ layer has a thickness in a range of about 25 nm to about 75 nm (e.g., about 50 nm). The unintentionally doped β-Ga₂O₃ layer defines a 2D electron gas channel between portions of the second n⁺⁺ Ga₂O₃. Dopants in the delta-doped β-(AlₓGa₁₋ₓ)₂O₃ layer are separated from the 2D electron gas channel.

A channel length, defined as the distance between an edge of the second n⁺⁺ Ga₂O₃ layer and an interface between the current blocking layer and the n⁻ doped drift layer at the aperture, is in a range of about 1 μm to about 11 μm. The length of the channel is selected to maximize breakdown voltage and minimize ON-state resistance of the transistor. The length of the of the channel is selected to prevent OFF-state leakage current from the aperture. A length of the aperture between portions of the current blocking layer is in a range of about 1 μm to about 20 μm.

A length of the current blocking layer is in a range of about 1 μm to about 3 μm. A breakdown voltage of the current blocking layer increases with increasing thickness of the current blocking layer. An acceptor doping concentration in the current blocking layer is in a range of about 1×10¹⁸ cm⁻³ to about 3×10¹⁸ cm⁻³. A breakdown voltage of the current blocking layer increases with an increase in the acceptor doping concentration in the current blocking layer. A power figure of merit of the transistor increases with an increasing thickness of the current blocking layer and acceptor doping in the current blocking layer. A peak electric field of the transistor increases with an increase in thickness of the current blocking layer in a range of about 0.8 μm to about 6 μm.

The β-Ga₂O₃ CAVETs were built in commercial TCAD Silvaco software. The β-Ga₂O₃ material and β-Ga₂O₃/(AlₓGa₁₋ₓ)₂O₃ (x=0.2) heterostructure properties such as bandgap and band alignment are based on experimental measurements. The bandgap for β-Ga₂O₃ and (AlₓGa₁₋ₓ)₂O₃ (x=0.2) was 4.8 eV and 5.2 eV, respectively, and the band offset between β-Ga₂O₃ and (AlₓGa₁₋ₓ)₂O₃ was 0.4 eV. As shown in FIG. 1A, the conventional CAVET consisted of n⁺⁺-doped β-Ga₂O₃ substrate, 8 μm n-type drift layer with a doping concentration of 1.5×10¹⁶ cm⁻³, 150 nm n⁺-doped channel layer with a doping concentration of 5×10¹⁷ cm⁻³, and a 50 nm Al₂O₃ dielectric layer under the gate. There were also two n⁺⁺-doped contact regions located under the source contacts. The CBL regions were located at both sides of the aperture above the drift layer. The length of the aperture was 20 μm, and the thickness of CBL was 0.8 μm. The channel length (L_{ch}) is the distance between the edge of the n⁺⁺-β-Ga₂O₃ contact region and the edge of the CBL region near the aperture side. The L_{ch} for the original CAVET and HEMT-CAVET model was set to be 5 μm. The drain current and on-resistance in the simulation is normalized by the device area defined by the total length of the device and the device width. The models used have been calibrated by the experimental results of E-mode β-Ga₂O₃ CAVETs, including transfer curves, reverse leakage, and breakdown voltages of the devices. FIG. 1B presents the simulated band structure along the cutline of conventional β-Ga₂O₃ CAVETs in FIG. 1A. The conduction band at the channel layer was close to the Fermi level due to the n⁺-doped channel layer. The threshold voltage (V_{TH}) of the device was still positive due to the electron-consuming effect from the gate. In the CBL region, the conduction band moved upward and was away from the Fermi level due to the implantation of nitrogen as deep-level dopants.

High doping concentration in the uniform-doped channel of conventional CAVETs may cause large reverse leakage through the conductive aperture, due at least in part to unmodulated electrons. To address this issue, a type of β-Ga₂O₃ CAVETs with delta-doped β-(AlₓGa₁₋ₓ)₂O₃/Ga₂O₃ heterostructure (which is denoted as HEMT-CAVETs) is disclosed for better gate controllability and reduced reverse leakage. As shown in FIG. 1C, the β-Ga₂O₃ HEMT-CAVET replaced the channel region and Al₂O₃ layer of the conventional β-Ga₂O₃ CAVETs with delta-doped β-(AlₓGa₁₋ₓ)₂O₃/Ga₂O₃ heterostructure, while the other regions remained the same. The heterostructure was composed of 50 nm (AlₓGa₁₋ₓ)₂O₃ layer and unintentionally doped (UID) β-Ga₂O₃ layer, where the delta-doped region had a thickness of 5 nm and a doping concentration of 1×10¹⁸ cm⁻³. FIG. 1D shows the band diagram extracted from the cutline of the β-Ga₂O₃ HEMT-CAVETs with different UID-Ga₂O₃ thicknesses in FIG. 1C. Compared with the conventional CAVET with a uniform-doped channel, the conduction band in the 2DEG channel of the HEMT-CAVET moved upward, indicating a lower concentration of 2DEG in the channel, resulting in E-mode operation with positive V_{TH}. In addition, no evidence of degeneration of R_{ON} was found in the HEMT-CAVET with the 2DEG channel. When the thickness of UID-Ga₂O₃ increased to 400 nm, the conduction band was still far from the Fermi level, indicating good carrier confinement and good electron modulation in the channel layer. These results indicate the superiority of the HEMT-CAVET design.

ON-State Performance of β-Ga₂O₃ HEMT-CAVET

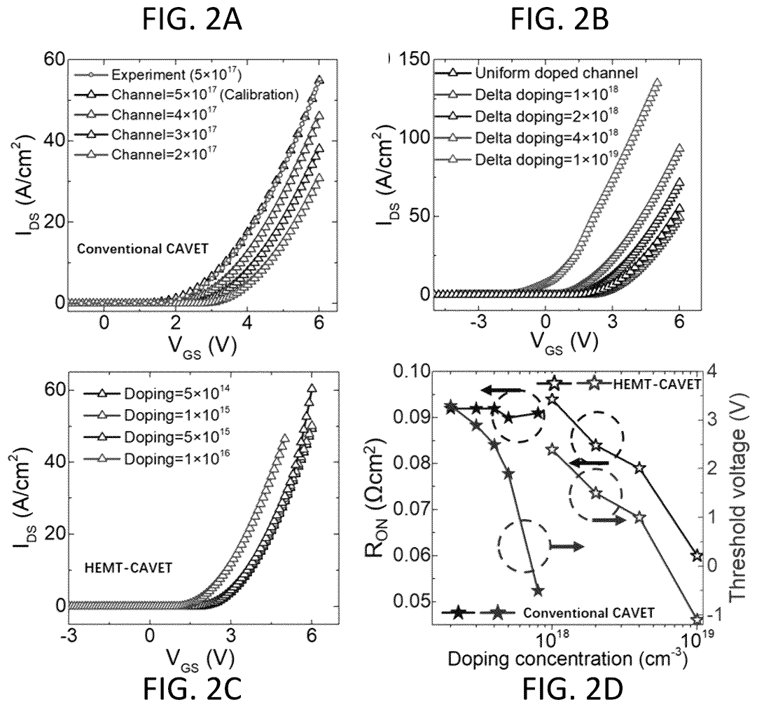

FIGS. 2A-2D show the ON-state performances of conventional β-Ga₂O₃ CAVETs and HEMT-CAVETs. For the transfer characteristics I_{DS}-V_{DS} curves of conventional CAVETs in FIG. 2A, the experiment result with a doping concentration of 5×10¹⁷ cm⁻³ in the channel layer and the simulated results with doping concentration from 5×10¹⁷, 4×10¹⁷, 3×10¹⁷, to 2×10¹⁷ cm⁻³ are presented. The simulation data agreed well with the experimental data. The extracted V_{TH} of the simulated conventional β-Ga₂O₃ CAVETs was 1.9, 2.5, 2.9, and 3.3 V, respectively. FIG. 2B shows the I_{DS}-V_{DS} curves of the β-Ga₂O₃ HEMT-CAVETs with delta-doping concentrations varying from 1×10¹⁸, 2×10¹⁸, 4×10¹⁸, to 1×10¹⁹ cm⁻³. The result of the conventional CAVET with a doping concentration of 5×10¹⁷ cm⁻³ in the channel was also shown as a comparison. The extracted V_{TH} of the HEMT-CAVETs with delta-doping concentrations from 1×10¹⁸, 2×10¹⁸, 4×10¹⁸, to 1×10¹⁹ cm⁻³ was 2.4, 1.5, 1.0, and ˜1.1 V, respectively. These results indicate that increasing either the doping concentration in the channel layer of the conventional β-Ga₂O₃ CAVET or the delta-doping concentration of the β-Ga₂O₃ HEMT-CAVET could decrease the V_{TH}. FIG. 2C shows the transfer curves of the β-Ga₂O₃ HEMT-CAVETs with different doping concentrations in the channel layer, while the delta-doping concentration was kept at 1×10¹⁸ cm⁻³. When the doping concentration in the channel layer increased from 5×10¹⁴ to 5×10¹⁵ cm⁻³, no evident difference was observed in the transfer curves of the devices. When the doping concentration was increased to 1×10¹⁶ cm⁻³, the V_{TH} of the devices showed a negative shift due to more unmodulated electrons. Therefore, control the channel doping concentration of the β-Ga₂O₃ HEMT-CAVETs to below 10¹⁶ cm⁻³ may help to avoid reduced V_{TH}. In the epitaxy growth technology of β-Ga₂O₃, such as MOCVD and MBE, the donor concentration of UID-Ga₂O₃ can be controlled to ˜10¹⁵ cm⁻³ or lower, indicating the feasibility of β-Ga₂O₃ HEMT-CAVETs. FIG. 2D shows the R_{ON} and V_{TH} of the conventional CAVETs and HEMT-CAVETs extracted from FIGS. 2A and 2B. For the conventional CAVETs, when the doping concentration in the channel increased from 2×10¹⁷ to 8×10¹⁷ cm⁻³, the V_{TH} of the devices decreased from 3.3 V to −0.5 V, but the R_{ON} of the devices was almost constant. For the HEMT-CAVETs, when the delta-doping concentration increased from 1×10¹⁸ to 1×10¹⁹ cm⁻³, the V_{TH} of the devices had a negative shift, but the R_{ON} of the devices decreased, which indicates a smaller R_{ON} than the conventional CAVETs. The significant decrease in the R_{ON} of HEMT-CAVET is due at least in part to the β-Ga₂O₃ 2DEG mobility model in the simulation. The high concentration dopants in the delta-doping region are separated from the 2DEG channel, and the electron mobility typically increases when the channel electrons concentration becomes higher.

OFF-State Performance of β-Ga₂O₃ HEMT-CAVET

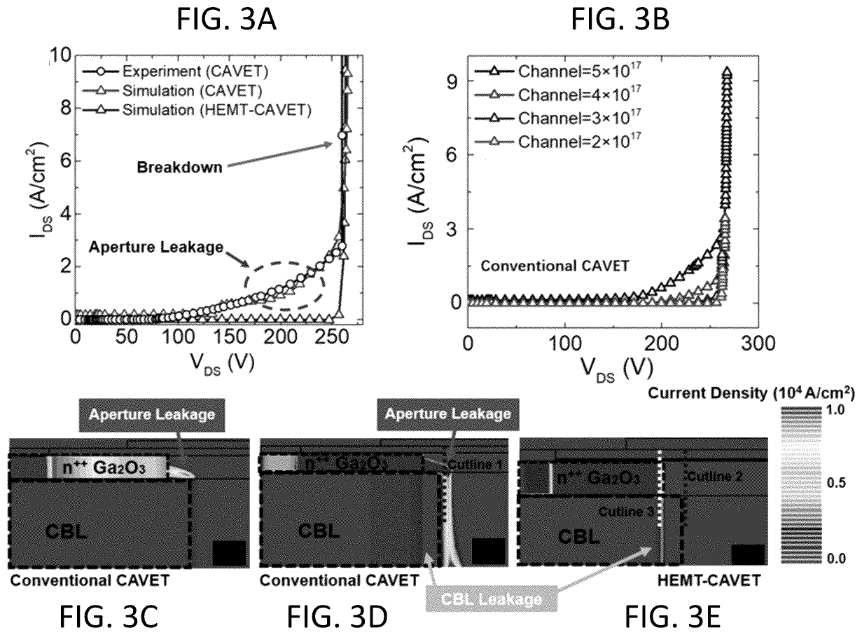

FIG. 3A shows the breakdown performance I_{D}s-V_{DS} curves of the conventional CAVET and HEMT-CAVET. The experiment and simulation results of conventional CAVETs were in good agreement with a doping concentration of 5×10¹⁷ cm⁻³ in the uniformly doped channel. The delta-doping concentration in the HEMT-CAVET was set at 2×10¹⁸ cm⁻³. The gate voltage of all devices was 0 V, and the breakdown was defined when the leakage current reached 10 A/cm² due to the relatively large reverse leakage of the device. These conditions are also used for the following sections for obtaining BV unless otherwise specified. In FIG. 3A, the simulated BV of the CAVETs was calibrated to be ˜265 V. However, it can be observed that the OFF-state leakage currents in the conventional CAVETs were significantly larger than those in the HEMT-CAVETs. Moreover, for the conventional CAVETs, the OFF-state leakage current decreased with decreasing doping concentration in the channel (FIG. 3B), but the device BV remained almost constant. These results indicate that the breakdown of CAVETs may occur through the CBL regions but not the aperture. To confirm this hypothesis, the current density distribution in the conventional CAVET and HEMT-CAVET were mapped out in FIGS. 3C-3E. In FIG. 3C, when the V_{DS} of the conventional CAVET was increased to 200 V, the large current density appeared by the edge of the CBL regions and through the aperture, indicating that the large OFF-state leakage was mainly from the aperture. In FIG. 3D, when the V_{DS} of the conventional CAVET was increased to BV of 265 V, the leakage flowed in the channel and through the aperture and the CBL region. These characteristics of OFF-state leakage distribution and breakdown are consistent with the observed experimental results. FIG. 3E shows the current density distribution of HEMT-CAVET at V_{DS}=265 V. In the HEMT-CAVET, the OFF-state leakage from the aperture was suppressed. The high current density at BV only flowed through the CBL region.

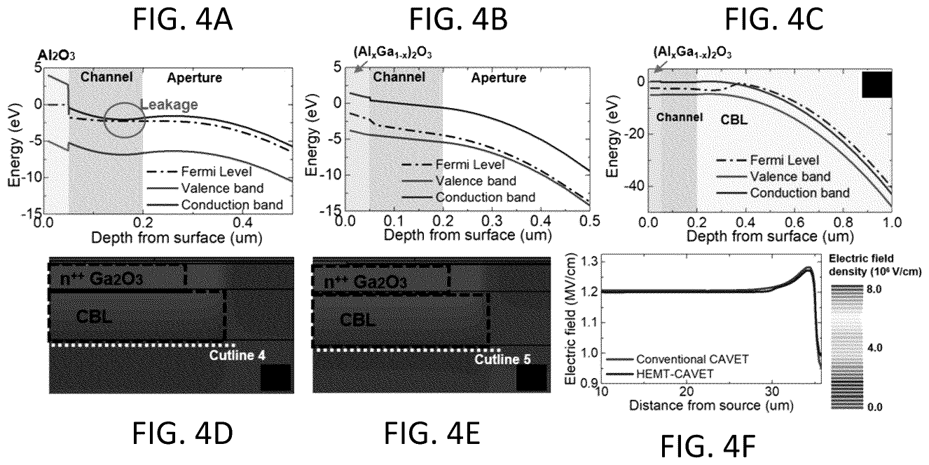

The band diagram (FIGS. 4A-4C) extracted from cutline 1, cutline 2, and cutline 3 in FIGS. 3D and 3E can explain the breakdown mechanism of conventional CAVET and HEMT-CAVET. From FIG. 4A, the conduction band at the bottom of the channel near the aperture bent downwards and was closer to the Fermi level. And this can cause the current flow from the conductive aperture at OFF-state due to the high doping concentration in the channel layer. However, as shown in FIG. 4B, this band bending was not observed in HEMT-CAVET. From FIG. 4C, the Fermi level at cutline 3 in FIG. 3E of HEMT-CAVET increased above the conduction band at high voltage in the CBL region, which indicates that the punch-through effect causes the surge of leakage current. FIGS. 4D and 4E show the 2D electric field distributions in conventional CAVET and HEMT-CAVET. The extracted electric field distribution in the horizontal direction from cutline 4 and cutline 5 are shown in FIG. 4F. The electric field distributions were similar at an OFF-state voltage of 265 V for conventional CAVET and HEMT-CAVET. Generally, the OFF-state leakage or breakdown of CAVETs may occur from the gate, from the aperture, or through the CBL region.

### Effect of Channel and Aperture Length on HEMT-CAVETs

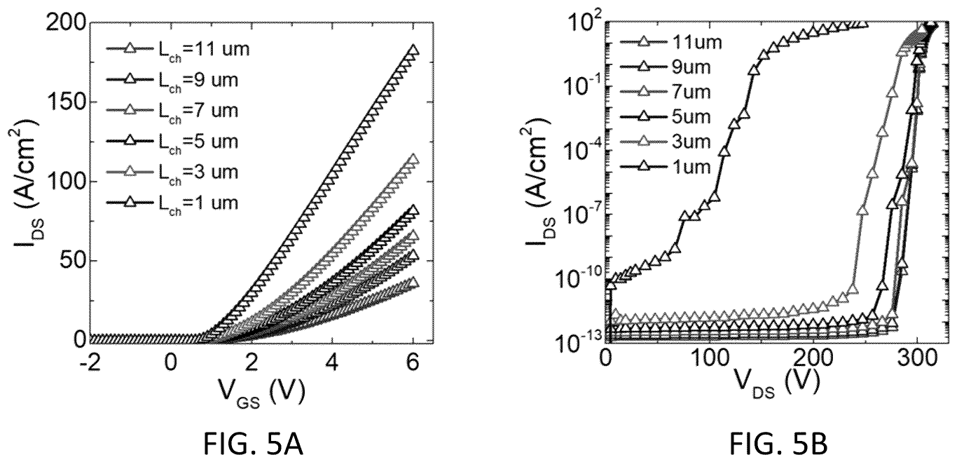

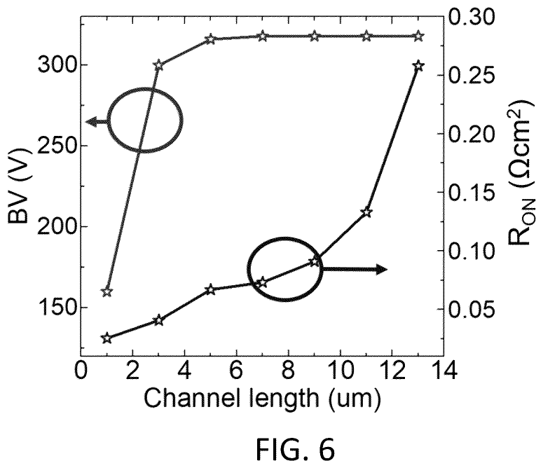

FIG. 5A shows the transfer curves of β-Ga₂O₃ HEMT-CAVETs with different L_{ch} from 1 to 11 μm. The V_{TH} was similar between these devices due to the same gate barrier. The ON-state current decreased with increasing L_{ch} since the channel resistance (R_{ch}) increased linearly with channel length. FIG. 5B shows the breakdown characteristics of these devices with different L_{ch}. When the L_{ch} was small (e.g., <3 μm), the breakdown voltage decreased significantly due to the short-channel effect. When the L_{ch} was large (e.g., >5 μm), the device breakdown characteristics were almost unchanged. With longer channels, the device breakdown was dominated by the CBL regions, while the leakage from the aperture was the main contributor to breakdown with shorter channels. FIG. 6 shows the BV and R_{ON} characteristics of β-Ga₂O₃ HEMT-CAVETs with different L_{ch}. With increasing L_{ch}, the device BV first increased and then plateaued when the L_{ch} was larger than 5 μm. The R_{ON} of the devices increased with increasing L_{ch}, and the increase rate of R_{ON} became larger at longer L_{ch} due to the larger R_{ch}. Therefore, the choice of L_{ch} can be optimized for the maximum BV and minimum R_{ON} for β-Ga₂O₃ HEMT-CAVETs.

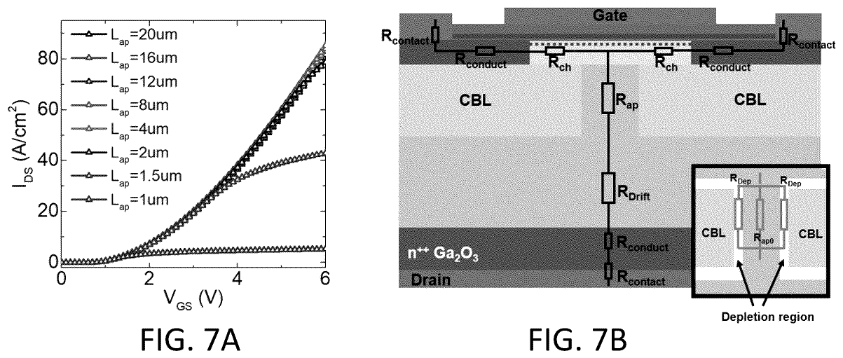

FIG. 7A shows the transfer characteristics of β-Ga₂O₃ HEMT-CAVETs with different aperture lengths (Lₐₚ) from 1 to 20 μm. When the Lₐₚ increased from 2 to 20 μm, the device transfer characteristics at V_{GS} from 0 to 6 V were almost unchanged. When the Lₐₚ decreased from 2 to 1 μm, significant degradation of device I_{DS} was observed. This can be explained by the increased R_{ON} of the devices with very small Lₐₚ. As shown in FIG. 7B, the total aperture resistance Rₐₚ can be considered as two resistors in parallel (Eq. 1). One is from the depletion region near the edge of CBL (R_{Dep}), and the other is from the aperture between the two depletion layers (Rₐₚ₀). When Lₐₚ>2 μm, the Rₐₚ₀ is much smaller than R_{Dep}, so the Rₐₚ₀ will be dominant in the Rₐₚ. When Lₐₚ<2 μm, the two depletion regions from the CBL will encroach the aperture, and the aperture between the two depletion regions will shrink, and Rₐₚ₀ will increase. As a result, R_{Dep} will be dominant in the Rₐₚ. This will increase the total R_{ON} of the device due to the increased Rₐₚ, thus degrading the ON-state performance. The total R_{ON} can be considered a simple model, as shown in Eq. 2.

$${R}_{ap} = {R}_{Dep} // {R}_{{ap}_{0}} \qquad ( 1 )$$

$${R}_{ON} = {R}_{ap} + {R}_{ch} + {R}_{drift} + {R}_{conduct} + {R}_{contact} \qquad ( 2 )$$

### Effect of CBL Design on Breakdown Voltage

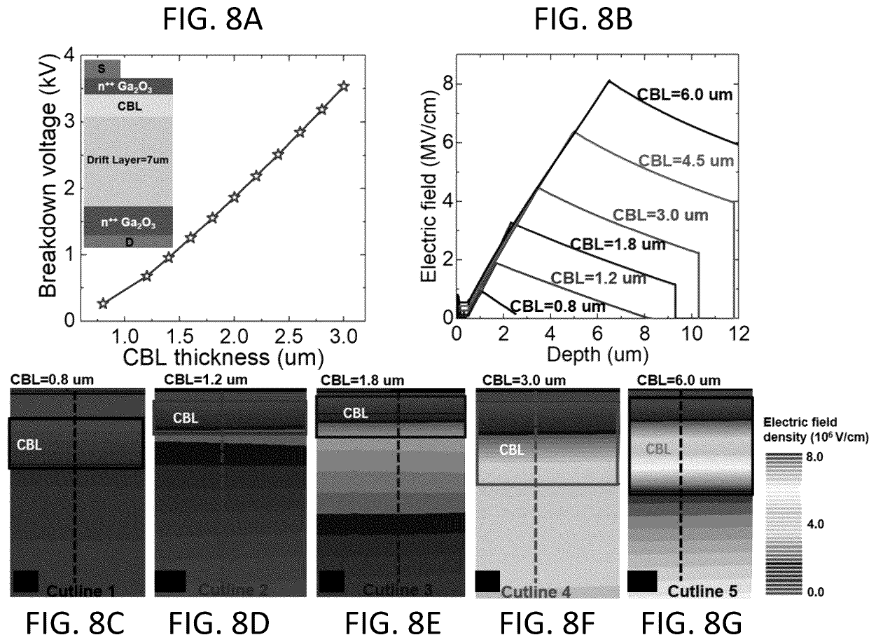

In FIGS. 8A-8G, a two-terminal structure from source to drain, including β-Ga₂O₃ drift layer, CBL region, and two n⁺⁺-doped β-Ga₂O₃ regions, was built to simulate the punch-through characteristics in the CBL region. The thicknesses of each layer were kept the same as those in the CAVETs. FIG. 8A shows the BV of the two-terminal structure with different CBL thicknesses. The BV of the structure with CBL thickness of 0.8 μm was calibrated to be 265 V. The structure BV increased linearly with CBL thickness. With 3 μm CBL, the simulated BV was increased to 3510 V. This trend can be explained by the electric field distribution in CBLs at the breakdown in FIG. 8B, which are extracted from FIGS. 8C-8G along their cutlines in CBLs. The peak electric field is concentrated at the bottom of the CBL region. With the CBL thickness increasing from 0.8, 1.2, 1.6, 3.0, 4.5 to 6.0 μm, the peak electric field increased from 0.95, 1.95, 3.35, 4.5, 6.5 to 8.0 MV/cm, respectively. This indicates that thicker CBL can withstand a higher electric field, resulting in higher BV, as observed in FIG. 8A.

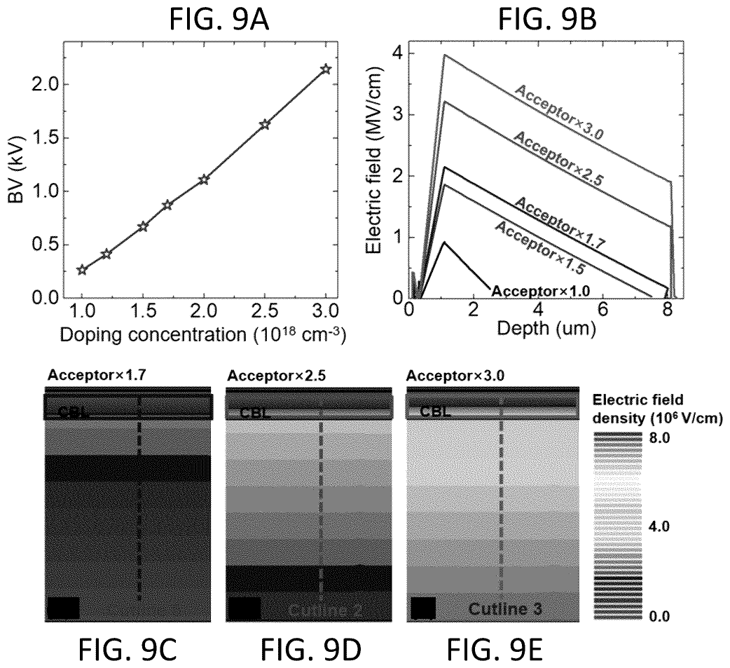

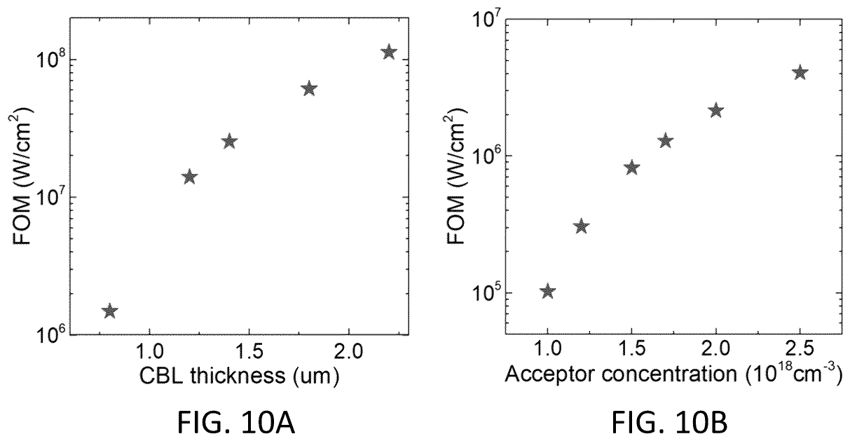

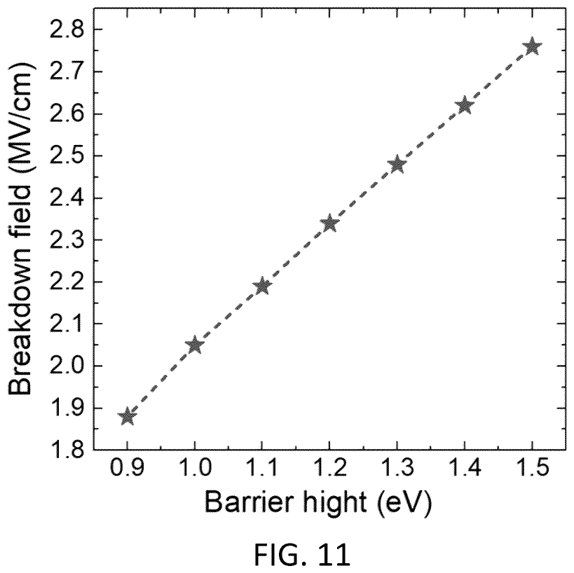

FIG. 9A shows the structure BV as a function of acceptor doping concentrations in the CBL. It was shown that the structure BV increased linearly with the doping concentration in the CBL. When the doping concentration in CBL increased to 3×10¹⁸ cm⁻³, the structure BV increased to 2150 V. FIG. 9B shows the electric field distributions extracted from cutlines in FIGS. 9C-9E. Increasing the CBL doping concentration increased the critical breakdown electric field in β-Ga₂O₃. When the CBL doping concentration increased from 1×10¹⁸ to 3×10¹⁸ cm⁻³, the peak electric field increased from 0.95 MV/cm to 4 MV/cm. This simulation of CBL breakdown shows an alternative route to kV-class β-Ga₂O₃ CAVETs by tunning the CBL thickness and doping. FIGS. 10A and 10B show the power figure of merit (FOM) versus different CBL thickness and acceptor implantation concentrations. Here, the whole CAVET structure was used for simulating the BV, not the two-terminal structure. The device power FOM increased with increasing CBL thickness and acceptor. This is because when the CBL thickness or acceptor concentration in CBL region increased, the device BV increased significantly, while the R_{ON} only had a slight change. It should be noted that the gate-to-drain breakdown is a concern of vertical devices. For Ga₂O₃ or (AlₓGa₁₋ₓ)₂O₃ materials, the measured Schottky barrier height is ˜0.9-1.4, resulting in a breakdown field of 1.85-2.65 MV/cm (FIG. 11). In addition, a gate dielectric is always preferred for HEMT-CAVET for a higher G-D breakdown field.

Table 1 compares the power figure of merit of different CAVETs, including conventional β-Ga₂O₃ CAVET, simulated β-Ga₂O₃ HEMT-CAVET, simulated β-Ga₂O₃ HEMT-CAVET with optimized breakdown fields, and state-of-art GaN CAVET. The fabrication feasibility of the HEMT-CAVET is also discussed here. In terms of CBL thickness, the CBL has already been fabricated with implantation, where the thickness can be larger than 2 μm. And the CBL thickness can be further increased by increasing the implantation energy and post-annealing temperature. Moreover, multiple ion implantation steps can also be used to fabricate thick CBL. In addition, it is also possible to realize very thick CBL through multi-step epitaxial regrowth. For the CBL acceptor doping concentrations, it can be increased by increasing the implantation doses during the implantation process.

TABLE 1
Device power FOM comparison between conventional
β-Ga₂O₃ CAVET, β-Ga₂O₃ HEMT-CAVET with different
breakdown fields, and state-of-art GaN CAVET.

| Device | Power FOM |
|---|---|
| Conventional CAVET | 7.6 × 10⁵ (W/cm²) |
| HEMT-CAVET | 1.2 × 10⁶ (W/cm²) |
| Optimized β-Ga₂O₃ HEMT- | 1.1 × 10⁹ (W/cm²) |
| CAVET | |
| (Breakdown field = 8 MV/cm) | |
| Optimized β-Ga₂O₃ HEMT- | 5.5 × 10⁸ (W/cm²) |
| CAVET | |
| (Breakdown field = 4 MV/cm) | |
| Optimized β-Ga₂O₃ HEMT- | 4.1 × 10⁸ (W/cm²) |
| CAVET | |
| (Breakdown field = 3 MV/cm) | |
| Optimized β-Ga₂O₃ HEMT- | 2.8 × 10⁸ (W/cm²) |
| CAVET | |
| (Breakdown field = 2 MV/cm) | |
| GaN CAVET | 2.84 × 10⁸ (W/cm²) |

Although this disclosure contains many specific embodiment details, these should not be construed as limitations on the scope of the subject matter or on the scope of what may be claimed, but rather as descriptions of features that may be specific to particular embodiments. Certain features that are described in this disclosure in the context of separate embodiments can also be implemented, in combination, in a single embodiment. Conversely, various features that are described in the context of a single embodiment can also be implemented in multiple embodiments, separately, or in any suitable sub-combination. Moreover, although previously described features may be described as acting in certain combinations and even initially claimed as such, one or more features from a claimed combination can, in some cases, be excised from the combination, and the claimed combination may be directed to a sub-combination or variation of a sub-combination.

Particular embodiments of the subject matter have been described. Other embodiments, alterations, and permutations of the described embodiments are within the scope of the following claims as will be apparent to those skilled in the art. While operations are depicted in the drawings or claims in a particular order, this should not be understood as requiring that such operations be performed in the particular order shown or in sequential order, or that all illustrated operations be performed (some operations may be considered optional), to achieve desirable results.

Accordingly, the previously described example embodiments do not define or constrain this disclosure. Other changes, substitutions, and alterations are also possible without departing from the spirit and scope of this disclosure.

What is claimed is:

1. A high electron mobility transistor current-aperture vertical electron transistor comprising:
a drain electrode;
a source electrode;
a gate electrode;
an n doped drift layer comprising β-Ga₂O₃;
a first n⁺⁺ Ga₂O₃ layer between the drain electrode and the n⁻ doped drift layer;
a current blocking layer, wherein a portion of the n⁻ doped drift layer defines an aperture in the current blocking layer;
a second n⁺⁺ Ga₂O₃ layer between the current blocking layer and the source electrode; and
a delta-doped β-(AlₓGa₁₋ₓ)₂O₃/Ga₂O₃ heterostructure between the portion of the n⁻ doped drift layer and the gate electrode, where x is 0.2.

2. The transistor of claim 1, wherein the delta-doped β-(AlₓGa₁₋ₓ)₂O₃/Ga₂O₃ heterostructure comprises a delta-doped β-(AlₓGa₁₋ₓ)₂O₃ layer and unintentionally doped β-Ga₂O₃ layer.

3. The transistor of claim 2, wherein the delta-doped β-(AlₓGa₁₋ₓ)₂O₃ layer has a thickness in a range of about 100 nm to about 500 nm.

4. The transistor of claim 2, wherein the delta-doped β-(AlₓGa₁₋ₓ)₂O₃ layer comprises a delta doped region having a thickness in a range of about 1 nm to about 10 nm and a doping concentration in a range of about 1×10¹⁸ cm⁻³ to about 1×10¹⁹ cm⁻³.

5. The transistor of claim 2, wherein the doping concentration is inversely related to a threshold voltage of the transistor.

6. The transistor of claim 4, wherein the delta doped region has a thickness of about 5 nm and a doping concentration of about 1×10¹⁸ cm⁻³.

7. The transistor of claim 2, wherein the (AlₓGa₁₋ₓ)₂O₃ layer has a thickness in a range of about 25 nm to about 75 nm.

8. The transistor of claim 7, wherein the (AlₓGa₁₋ₓ)₂O₃ layer has a thickness of about 50 nm.

9. The transistor of claim 2, wherein the unintentionally doped β-Ga₂O₃ layer defines a 2D electron gas channel between portions of the second n⁺⁺ Ga₂O₃.

10. The transistor of claim 9, wherein dopants in the delta-doped β-(AlₓGa₁₋ₓ)₂O₃ layer are separated from the 2D electron gas channel.

11. The transistor of claim 1, wherein a channel length, defined as the distance between an edge of the second n⁺⁺ Ga₂O₃ layer and an interface between the current blocking layer and the n doped drift layer at the aperture, is in a range of about 1 μm to about 11 μm.

12. The transistor of claim 11, wherein the length of the of the channel is selected to maximize breakdown voltage and minimize ON-state resistance of the transistor.

13. The transistor of claim 11, wherein the length of the of the channel is selected to prevent OFF-state leakage current from the aperture.

14. The transistor of claim 11, wherein a length of the aperture between portions of the current blocking layer is in a range of about 1 μm to about 20 μm.

15. The transistor of claim 1, wherein a length of the current blocking layer is in a range of about 1 μm to about 3 μm.

16. The transistor of claim 15, wherein a breakdown voltage of the current blocking layer increases with increasing thickness of the current blocking layer.

17. The transistor of claim 1, wherein an acceptor doping concentration in the current blocking layer is in a range of about 1×10¹⁸ cm⁻³ to about 3×10¹⁸ cm⁻³.

18. The transistor of claim 17, wherein a breakdown voltage of the current blocking layer increases with an increase in the acceptor doping concentration in the current blocking layer.

19. The transistor of claim 17, wherein a power figure of merit of the transistor increases with an increasing thickness of the current blocking layer and acceptor doping in the current blocking layer.

20. The transistor of claim 1, wherein a peak electric field of the transistor increases with an increase in thickness of the current blocking layer in a range of about 0.8 μm to about 6 μm.
